(19) United States
(12) Patent Application Publication
(10) Pub. No.: US 2023/0197581 A1
(43) Pub. Date: Jun. 22, 2023

(54) POWER SEMICONDUCTOR MODULE AND METHOD OF MANUFACTURING THE SAME

(71) Applicant: LX Semicon Co., Ltd., Daejeon (KR)

(72) Inventors: Tae Ryong KIM, Daejeon (KR); Deog Soo KIM, Daejeon (KR); Dong Woo MOON, Daejeon (KR)

(73) Assignee: LX Semicon Co., Ltd., Daejeon (KR)

(21) Appl. No.: 18/084,429

(22) Filed: Dec. 19, 2022

(30) Foreign Application Priority Data
Dec. 22, 2021 (KR) 10-2021-0185134

(51) Int. Cl. H01L 23/495; H01L 23/31; H01L 23/00; H01L 23/29; H01L 21/56

(52) U.S. Cl. CPC H01L 23/49562; H01L 21/56; H01L 23/293; H01L 23/3107; H01L 23/49503; H01L 24/48; H01L 24/32; H01L 24/73; H01L 2224/32245; H01L 2224/48245; H01L 2224/73265

(57) ABSTRACT

The present disclosure provides a power semiconductor module in which a lead frame paddle is extended to form a source lead, a source electrode of a power semiconductor die is electrically connected to the lead frame paddle, a drain electrode is insulated from the lead frame paddle, and a part of the lead frame paddle is exposed to the outside of a mold.

### CROSS REFERENCE TO RELATED APPLICATION

This application claims priority to Republic of Korea Patent Application No. 10-2021-0185134, filed on Dec. 22, 2021, which is hereby incorporated by reference in its entirety.

### BACKGROUND

### 1. Field of Technology

The present disclosure relates to a power semiconductor module.

### 2. Related Technology

A semiconductor that is used in a device for processing high power, such as a converter or an inverter, is called a power semiconductor. The power semiconductor may be an insulated gate bipolar transistor (IGBT), a metal oxide semiconductor field effect transistor (MOSFET), or a diode, for example, and may have characteristics in that internal pressure is great and a high current may flow.

The power semiconductor may have a great switching loss and/or a great conduction loss due to high internal pressure and a high current. If a loss is great in the power semiconductor, the amount of heat dissipated is increased. The power semiconductor may have the great amount of heat dissipated due to the switching loss and/or the conduction loss.

If the amount of heat dissipated is not controlled to a proper level, the physical properties of a device may be changed, and the power semiconductor may not perform its own function. In order to prevent such problems, heat dissipation means may be added to the power semiconductor. A power semiconductor module may include at least power semiconductor within one package, and may have a proper heat dissipation form.

The heat dissipation means that is included in the power semiconductor module may have a great difference in heat dissipation performance depending on a location at which the heat dissipation means is disposed. A conventional power semiconductor module does not have high heat dissipation performance because the heat dissipation means is disposed within a mold.

Furthermore, in the conventional power semiconductor module, the heat dissipation means has a problem in that electromagnetic interference (EMI) noise is amplified because the heat dissipation means is attached to a part at which a voltage is floated and functions like an antenna.

The discussions in this section are only to provide background information and does not constitute an admission of prior art.

### SUMMARY

In such a background, in an aspect, the present disclosure is to provide a technology for improving heat dissipation performance of a power semiconductor module. In another aspect, the present disclosure is intended to provide a technology for reducing EMI noise in a power semiconductor module.

In an aspect, the present disclosure provides a power semiconductor module including: a lead frame paddle; a metal plate disposed on the lead frame paddle in a state of being insulated from the lead frame paddle; a power semiconductor die having a first electrode formed on one side thereof and a second electrode formed on the other side thereof, the first electrode being disposed toward the metal plate; a first lead electrically connected to the first electrode through the metal plate; and a second lead extended from the lead frame paddle and electrically connected to the second electrode.

In another aspect, the present disclosure provides a method of manufacturing a power semiconductor module including: disposing a lead frame comprising a lead frame paddle, a first lead, a second lead, and a gate lead, wherein the second lead is connected to the lead frame paddle; disposing a metal plate on the lead frame paddle in a state of being insulated from the lead frame paddle; bonding, to the metal plate, a first electrode of a power semiconductor die having the first electrode formed on one side thereof and a second electrode formed on the other side thereof; electrically connecting the metal plate and the first lead and electrically connecting the second electrode and the second lead; and forming a mold such that the mold surrounds the power semiconductor die.

In still another aspect, the present disclosure provides a power semiconductor module including: a lead frame paddle; a power semiconductor die having a first electrode formed on one side thereof and a second electrode formed on the other side thereof, the second electrode being bonded to the lead frame paddle; a first lead electrically connected to the first electrode; and a second lead extended from the lead frame paddle.

In still another aspect, the present disclosure provides a method of manufacturing a power semiconductor module including: disposing a lead frame comprising a lead frame paddle, a first lead, a second lead, and a gate lead, wherein the second lead is connected to the lead frame paddle; bonding, to the lead frame paddle, a second electrode of the power semiconductor die having a first electrode formed on one side thereof and the second electrode formed on the other side thereof; electrically connecting the first lead and the first electrode; and forming a mold such that the mold surrounds the power semiconductor die.

When the power semiconductor die is a metal oxide semiconductor field effect transistor (MOSFET), the first electrode may be a drain electrode and the second electrode may be a source electrode. When the power semiconductor is an insulated gate bipolar transistor (IGBT), the first electrode may be a collector electrode and the second electrode may be an emitter electrode.

As described above, according to the present disclosure, heat dissipation performance of the power semiconductor module can be improved. Furthermore, according to the present disclosure, EMI noise in the power semiconductor module can be reduced.

### BRIEF DESCRIPTION OF THE DRAWINGS

FIG. 1 is a construction diagram of a power device according to an embodiment.

FIG. 2 is a diagram illustrating EMI noise that occurs around a power semiconductor in one arm.

FIG. 3 is a perspective top view of a common power semiconductor module.

FIG. 4 is a cross-sectional view taken along line X-X′ in FIG. 3.

FIG. 5 is a perspective top view of a power semiconductor module according to a first example of an embodiment.

FIG. 6 is a cross-sectional view taken along line X-X′ in FIG. 5.

FIGS. 7 to 11 are exemplary diagrams illustrating processes of a method of manufacturing a power semiconductor module according to a first example.

FIG. 12 is a perspective top view of a power semiconductor module according to a second example of an embodiment.

FIG. 13 is a cross-sectional view taken along line X-X′ in FIG. 12.

FIGS. 14 to 18 are exemplary diagrams illustrating processes of a method of manufacturing a power semiconductor module according to a second example.

### DETAILED DESCRIPTION OF EMBODIMENTS

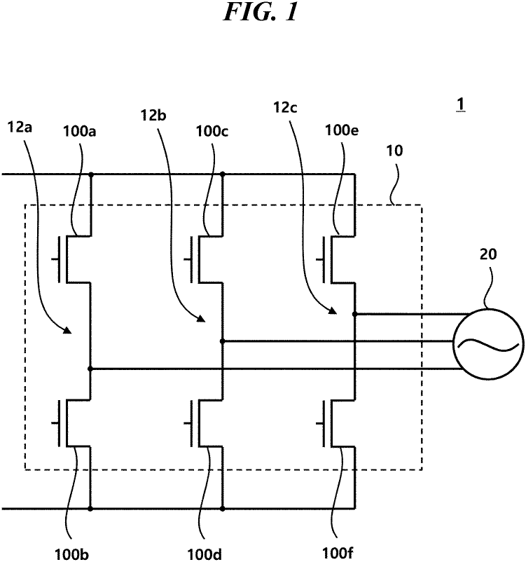

FIG. 1 is a construction diagram of a power device according to an embodiment.

Referring to FIG. 1, the power device 1 may include an inverter 10 and a motor 20.

The motor 20 may provide power to an electric vehicle or a fuel cell vehicle. The motor 20 may be driven by being supplied with three-phase alternating current (AC) power.

The inverter 10 may supply the AC power to the motor 20. The inverter 10 may receive direct current (DC) power from a battery or a fuel cell, and may convert the DC power into the AC power. Furthermore, the inverter 10 may output the AC power to the motor 20.

The inverter 10 may include a plurality of power semiconductors 100a to 100f, and may convert the DC power into the AC power through on-off control over the plurality of power semiconductors 100a to 100f. For example, the inverter 10 may supply a positive voltage to the motor 20 by making on the first power semiconductor 100a and off the second power semiconductor 100b in a first time interval of one interval, and may supply a negative voltage to the motor 20 by making off the first power semiconductor 100a and on the second power semiconductor 100b in a second time interval of one interval.

A group of power semiconductors that are disposed in series in a high voltage line and low voltage line on an input side thereof is called an arm. For example, a first power semiconductor 100a and a second power semiconductor 100b may constitute a first arm 12a, a third power semiconductor 100c and a fourth power semiconductor 100d may constitute a second arm 12b, and a fifth power semiconductor 100e and a sixth power semiconductor 100f may constitute a third arm 12c.

In the arm, an upper power semiconductor and a lower power semiconductor may be controlled so that they do not become simultaneously on. For example, in the first arm 12a, the first power semiconductor 100a and the second power semiconductor 100b may alternately become on and off without becoming simultaneously on.

Each of the power semiconductors 100a to 100f may be applied with a high voltage in the state in which each of the power semiconductors 100a to 100f has become off. For example, if the second power semiconductor 100b becomes off in the state in which the first power semiconductor 100a has become on, an input voltage may be applied to the second power semiconductor 100b without change. The input voltage may be a relatively high voltage. Internal pressure of each of the power semiconductors 100a to 100f may be designed to a high level so that each of the power semiconductors 100a to 100f can withstand such a high voltage.

Each of the power semiconductors 100a to 100f may conduct a high current in the state in which each of the power semiconductors 100a to 100f has been on. The motor 20 is driven at a relatively high current. Such a high current may be supplied to the motor 20 through a power semiconductor that has become on.

A high voltage that is applied to each of the power semiconductors 100a to 100f may cause a high switching loss. A high current that passes through the power semiconductors 100a to 100f may cause a high conduction loss. In order to discharge heat generated by such a loss, the power semiconductors 100a to 100f may be packaged as a power semiconductor module including heat dissipation means.

All the power semiconductors 100a to 100f that are included in the inverter 10 may be packaged as one power semiconductor module.

For example, the first power semiconductor 100a, the second power semiconductor 100b, the third power semiconductor 100c, the fourth power semiconductor 100d, the fifth power semiconductor 100e, and the sixth power semiconductor 100f may be packaged as one power semiconductor module. In order to increase the current capacity, an additional power semiconductor that is disposed in parallel to each of the power semiconductors 100a to 100f may be further present. In such a case, the number of power semiconductors that are included in the power semiconductor module may be more than 6. FIG. 1 illustrates only power semiconductors having a transistor form. However, the inverter 10 may further include a power semiconductor having a diode form, in addition to the power semiconductor having a transistor form. For example, a first diode (not illustrated) may be further disposed in parallel to the first power semiconductor 100a. A second diode (not illustrated) may be further disposed in parallel to the second power semiconductor 100b. Furthermore, such diodes may be packaged along with one power semiconductor module.

Power semiconductors that constitute each arm may be packaged as one power semiconductor module.

For example, the first power semiconductor 100a and the second power semiconductor 100b that constitute the first arm 12a may be packaged as one power semiconductor module. The third power semiconductor 100c and the fourth power semiconductor 100d that constitute the second arm 12b may be packaged as another power semiconductor module. The fifth power semiconductor 100e and the sixth power semiconductor 100f that constitute the third arm 12c may be packaged as another power semiconductor module. In order to increase the current capacity, an additional power semiconductor that is disposed in parallel to each of the power semiconductors 100a to 100f may be further present. In such a case, the number of power semiconductors that are included in the power semiconductor module may be more than 2. Furthermore, each arm may further include a power semiconductor having a diode form, in addition to the power semiconductor having a transistor form. Such diodes may also be packaged along with one power semiconductor module.

Each of the power semiconductors 100a to 100f may be packaged as one power semiconductor module.

For example, the first power semiconductor 100a may be packaged as one power semiconductor module, the second power semiconductor 100b may be packaged as another power semiconductor module, and the third power semiconductor 100c may be packaged as still another power semiconductor module. In order to increase the current capacity, an additional power semiconductor that is disposed in parallel to each of the power semiconductors 100a to 100f may be further present. In such a case, the number of power semiconductors that are included in the power semiconductor module may be two or more. Furthermore, a diode may additionally further included in each power semiconductor module.

Hereinafter, an embodiment in which each of the power semiconductors 100a to 100f is packaged as one power semiconductor module is chiefly described.

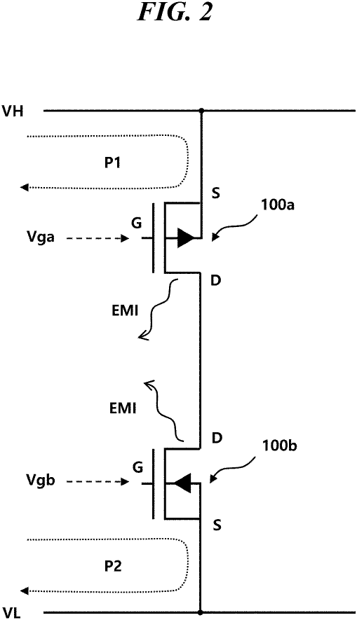

FIG. 2 is a diagram illustrating EMI noise that occurs around a power semiconductor in one arm.

Referring to FIG. 2, the first power semiconductor 100a and the second power semiconductor 100b may be connected in series in an arm. A high voltage VH may be supplied to the upper side of the first power semiconductor 100a, and a low voltage VL may be connected to the lower side of the second power semiconductor 100b.

In the first power semiconductor 100a, a source electrode S may be connected to the high voltage VH, and a drain electrode D may be connected to the drain electrode D of the second power semiconductor 100b. Furthermore, in the second power semiconductor 100b, a source electrode S may be connected to the low voltage VL.

In such an arrangement, when the first power semiconductor 100a and the second power semiconductor 100b become off by gate voltages Vga and Vgb, the drain electrodes D of the first power semiconductor 100a and the second power semiconductor 100b may be floated. When the drain electrodes are floated, EMI noise may occur a lot because a voltage in a corresponding electrode is easily changed.

In a common power semiconductor module, heat dissipation means is disposed in the drain electrode D of a power semiconductor. Such heat dissipation means may have a problem in that EMI noise is amplified because the heat dissipation means functions like an antenna in the state in which the drain electrode D has been floated.

The first gate voltage Vga is a voltage that is formed between the gate electrode G and source electrode S of the first power semiconductor 100a, and may be a lot or less influenced by EMI noise that is introduced from the outside depending on a characteristic of a first path P1. Furthermore, a second gate voltage Vgb is a voltage that is formed between the gate electrode G and source electrode S of the second power semiconductor 100b, and may be a lot or less influenced by EMI noise that is introduced from the outside depending on a characteristic of a second path P2.

In order for the first gate voltage Vga to be less influenced by EMI noise, the first path P1 needs to be short, and linear resistance of the first path P1 needs to be small. Furthermore, in order for the second gate voltage Vgb to be less influenced by EMI noise, the second path P2 needs to be short, and linear resistance of the second path P2 needs to be small.

In a common power semiconductor module, heat dissipation means does not contribute to reducing linear resistance of the paths P1 and P2 because the heat dissipation means is disposed in the drain electrode D and separate heat dissipation means is not disposed in the source electrode S.

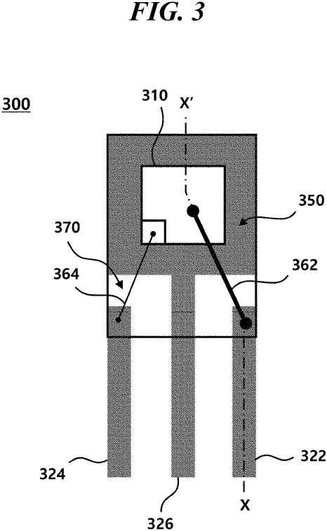

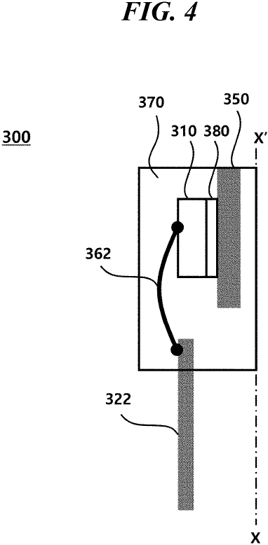

FIG. 3 is a perspective top view of a common power semiconductor module. FIG. 4 is a cross-sectional view taken along line X-X′ in FIG. 3.

Referring to FIGS. 3 and 4, in a common power semiconductor module 300, a power semiconductor die 310 may be bonded to a lead frame paddle 350 by soldering.

In the power semiconductor die 310, a drain electrode may be bonded to the lead frame paddle 350. Furthermore, in the power semiconductor module 300, a drain lead 326 may be extended from the lead frame paddle 350.

A source lead 322 may be insulated from the lead frame paddle 350, and may be connected to the source electrode of the power semiconductor die 310 through a first wire 362. A gate lead 324 may be connected to the gate electrode of the power semiconductor die 310 through a second wire 364.

Furthermore, a mold 370 may be formed to surround the power semiconductor die 310, the first wire 362, the second wire 364, and the lead frame paddle 350.

In general, the power semiconductor module 300 may be bonded to a heat sink for heat dissipation. In order to insulate the drain electrode from the heat sink, the lead frame paddle 350 may be disposed within the mold 370 in the state in which the lead frame paddle 350 has been insulated.

In such an arrangement of the common power semiconductor module 300, heat dissipation performance may be degraded because the lead frame paddle 350, that is, heat dissipation means, is disposed within the mold 370. Thermal conductivity of copper that constitutes the lead frame paddle 350 is about 401 W/mK. In contrast, thermal conductivity of the mold 370 is commonly 0.8 W/mK. Accordingly, in the structure of the power semiconductor module 300, there is a problem in that heat is confined within the mold 370 without being rapidly discharged due to the mold 370.

Furthermore, in such an arrangement structure of the common power semiconductor module 300, there is a problem in that the common power semiconductor module 300 is vulnerable to EMI noise because the lead frame paddle 350 comes into contact with the drain electrode.

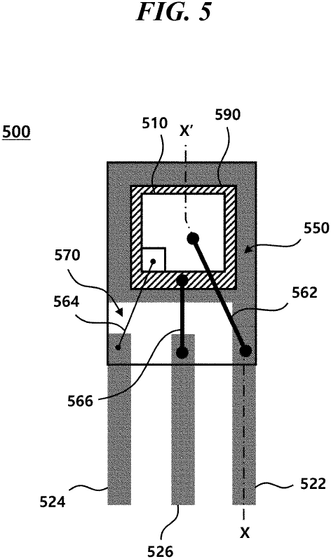

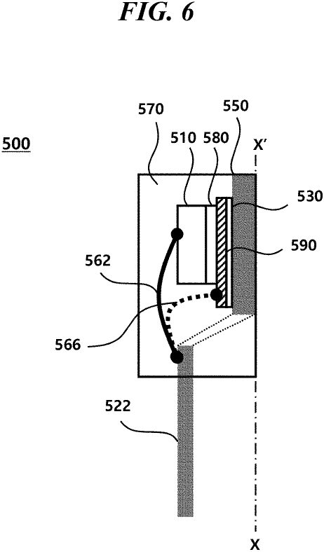

FIG. 5 is a perspective top view of a power semiconductor module according to a first example of an embodiment. FIG. 6 is a cross-sectional diagram taken along line X-X′ in FIG. 5.

Referring to FIGS. 5 and 6, a power semiconductor module 500 may include a lead frame paddle 550, a metal plate 590, a power semiconductor die 510, a drain lead 526, a source lead 522, a gate lead 524, a mold 570, etc.

A power semiconductor having a wafer state, which has not been packaged, may be called a power semiconductor die. The power semiconductor may be basically divided into a switch element and a rectifier element. The switch element may be an insulated gate bipolar transistor (IGBT) or a metal oxide semiconductor field effect transistor (MOSFET). The rectifier element may be a well-known diode. In an embodiment described hereinafter, the power semiconductor die may have a switch element form.

The metal plate 590 may be disposed on the lead frame paddle 550 in the state in which the metal plate 590 has been insulated from the lead frame paddle 550. An insulating member 530 may be attached on the lead frame paddle 550, and the metal plate 590 may be attached on the insulating member 530. The insulating member 530 may be an insulating tape, for example, and may be an insulating substrate, such as ceramics.

The lead frame paddle 550 may have a square form, and the metal plate 590 may also have a square form. The area of the metal plate 590 may be smaller than the area of the lead frame paddle 550. When viewed from the top (when viewed from the same gaze as FIG. 5), the metal plate 590 may be disposed inside the lead frame paddle 550.

A drain electrode may be formed on one side of the power semiconductor die 510, and a source electrode may be formed on the other side the power semiconductor die 510, which is opposite to the one side. Furthermore, the power semiconductor die 510 may be disposed so that the drain electrode of the power semiconductor die 510 is directed toward the metal plate 590.

The drain electrode of the power semiconductor die 510 may be bonded to the metal plate 590 through a bonding member 580. The bonding member 580 may be a soldering bonding member, for example. The drain electrode of the power semiconductor die 510 may be bonded to the metal plate 590 by soldering.

The area of the metal plate 590 may be greater than the area of the power semiconductor die 510. When viewed from the top, the power semiconductor die 510 may be disposed inside the metal plate 590. Furthermore, the metal plate 590 and the drain lead 526 may be electrically connected through a part that belongs to the metal plate 590 and that is not covered by the power semiconductor die 510.

For example, the metal plate 590 may be connected to the drain lead 526 through a third wire 566. Furthermore, through such a connection, the drain electrode of the power semiconductor die 510 may be electrically connected to the drain lead 526.

The source electrode and gate electrode of the power semiconductor die 510 may be disposed on the side opposite to the drain electrode. The source electrode may be electrically connected to the source lead 522 through a first wire 562. The gate electrode may be electrically connected to the gate lead 524 through a second wire 564.

The source lead 522 may be extended from the lead frame paddle 550. The gate lead 524 and the drain lead 526 may be physically separated from the lead frame paddle 550.

In such an arrangement and connection state, the power semiconductor die 510, the metal plate 590, the first wire 562, the second wire 564, and the third wire 566 may be surrounded by the mold 570. The mold may be formed of an epoxy molding compound (EMC).

A part that belongs to the source lead 522 and that is bonded to the first wire 562 may be included within the mold 570, and the remaining parts of the source lead 522 may be exposed to the outside of the mold 570. A part that belongs to the gate lead 524 and that is bonded to the second wire 564 may be included within the mold 570, and the remaining parts of the gate lead 524 may be exposed to the outside of the mold 570. A part that belongs to the drain lead 526 and that is bonded to the third wire 566 may be included within the mold 570, and the remaining parts of the drain lead 526 may be exposed to the outside of the mold 570.

One surface of the lead frame paddle 550 may be exposed to the outside of the mold 570. Furthermore, the exposed part of the lead frame paddle 550 may come into contact with a component capable of heat dissipation. For example, the exposed part of the lead frame paddle 550 may be bonded to the heat sink, and may be exposed to the air.

A part of the lead frame paddle 550 may be exposed to the outside of the mold 570. For example, a part of the lead frame paddle 550 may protrude to the outskirts of the mold 570. The protruded part may have both one surface and the other surface exposed to the outside of the mold 570. When viewed from surfaces that come into contact with each other, the bottom of the lead frame paddle 550 may be exposed to the outside of the mold 570. A part of the top of the lead frame paddle 550 may be disposed to thermally come into contact with the metal plate 590 within the mold 570. The remainder of the top of the lead frame paddle 550 may be exposed to the outside of the mold 570.

As described above, in the first example, heat dissipation performance can be improved because the lead frame paddle 550 is exposed to the outside of the mold 570, and EMI performance can also be improved because the lead frame paddle 550 is electrically connected to the source electrode of the power semiconductor die 510.

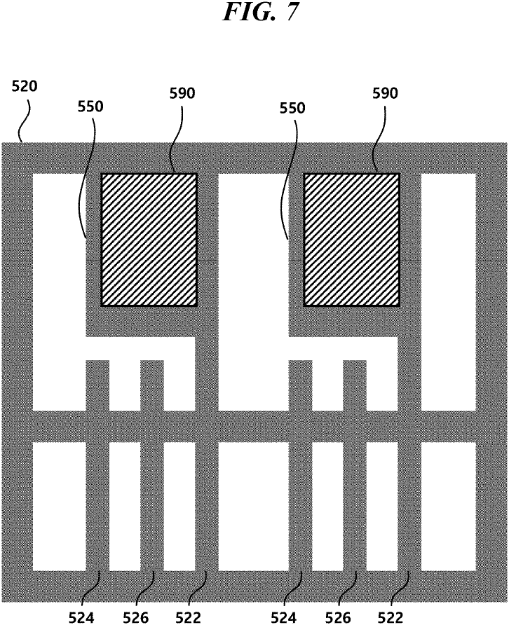

FIGS. 7 to 11 are exemplary diagrams illustrating processes of a method of manufacturing a power semiconductor module according to a first example.

Referring to FIG. 7, in a first process, a lead frame 520 in which a plurality of lead frame paddles 550, a plurality of source leads 522, a plurality of gate leads 524, and a plurality of drain leads 526 have been formed may be disposed.

In the lead frame 520, each of the lead frame paddles 550 may be connected to the source lead 522. The gate lead 524 and the drain lead 526 may not be connected to each of the lead frame paddles 550.

Furthermore, in a second process, in the state in which the metal plates 590 have been insulated from the lead frame paddles 550, respectively, the metal plate 590 may be disposed on the lead frame paddle 550. The metal plate 590 may be formed of Cu-series metal or may be formed of Al-series metal.

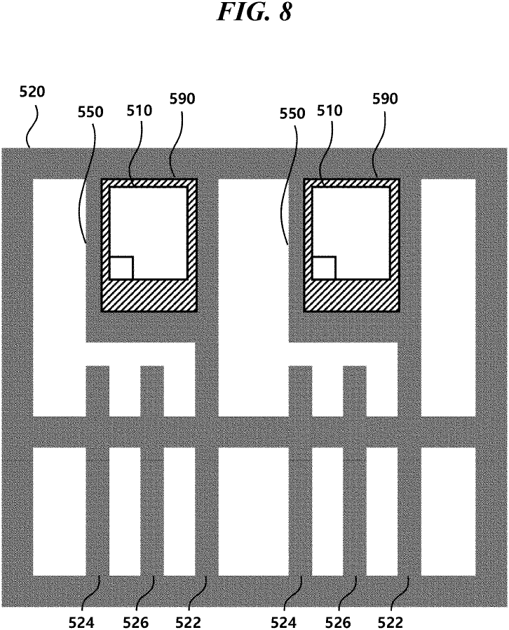

Referring to FIG. 8, in a third process, the power semiconductor die 510 may be bonded to the metal plate 590. A drain electrode may be formed on one side of the power semiconductor die 510, and a source electrode and a gate electrode may be formed on the other side of the power semiconductor die 510. The drain electrode may be bonded to the metal plate 590 by soldering.

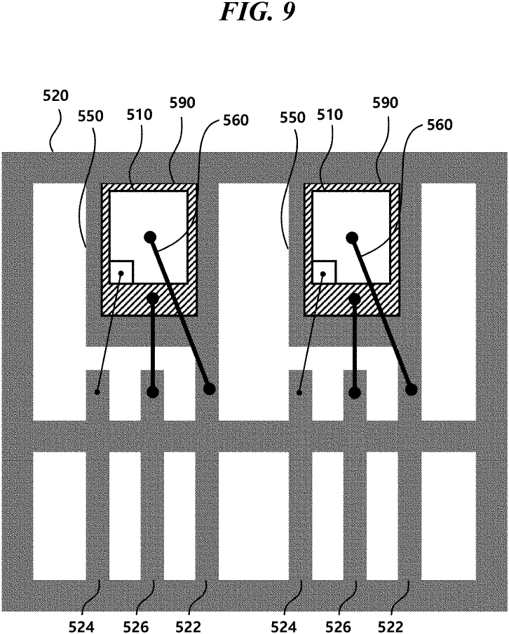

Referring to FIG. 9, in a fourth process, each electrode may be electrically connected to the lead 522, 524, 526, through a wire 560. The source electrode may be electrically connected to the source lead 522 through the wire. The gate electrode may be electrically connected to the gate lead 524 through the wire. The drain electrode may be electrically connected to the metal plate 590. The metal plate 590 may be electrically connected to the drain lead 526 through the wire.

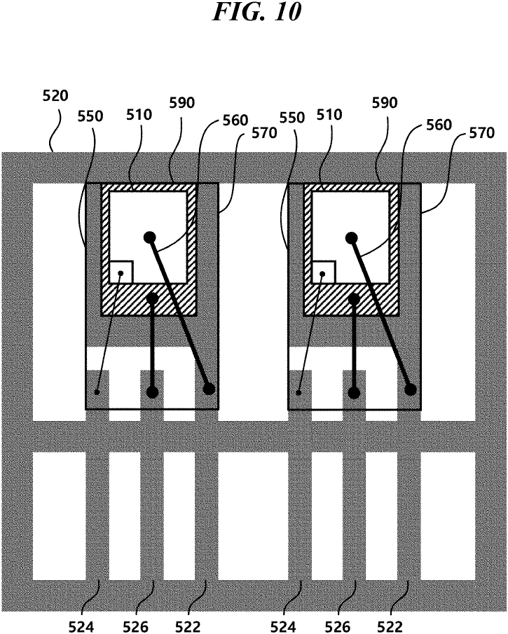

Referring to FIG. 10, in a fifth process, the power semiconductor die 510, the metal plate 590, and the wires 560 may be surrounded by the mold 570. In this case, the mold 570 may be formed so that one surface of the lead frame paddle 550 is exposed to the outside of the mold 570.

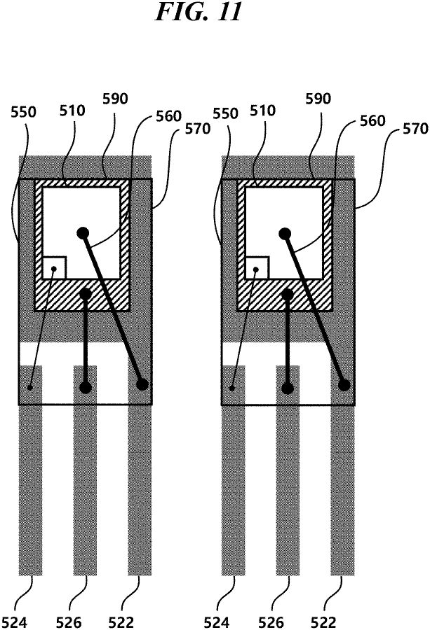

Referring to FIG. 11, in a sixth process, as an unnecessary part is removed from the lead frame, the power semiconductor module may be manufactured.

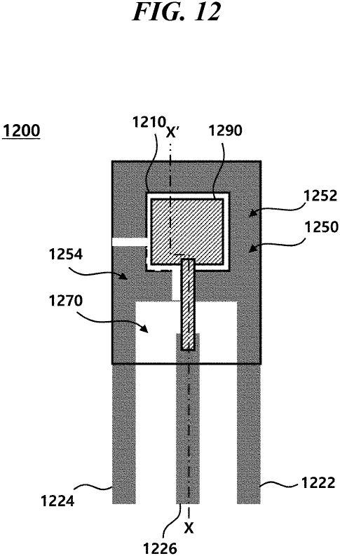

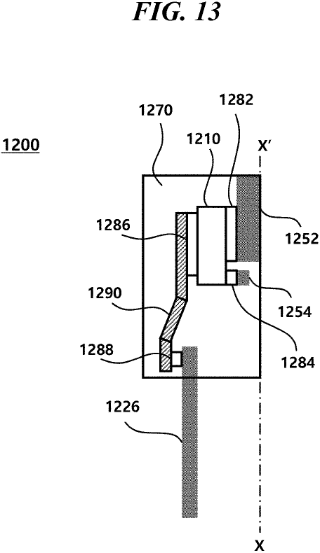

FIG. 12 is a perspective top view of a power semiconductor module according to a second example of an embodiment. FIG. 13 is a cross-sectional diagram taken along line X-X′ in FIG. 12.

Referring to FIGS. 12 and 13, a power semiconductor module 1200 may include a lead frame paddle 1250, a power semiconductor die 1210, a drain lead 1226, a source lead 1222, a gate lead 1224, a connection member 1290, a mold 1270, etc.

The lead frame paddle 1250 may be divided into two regions. A first paddle 1252 may be formed in a first region of the two regions, and a second paddle 1254 may be formed in a second region of the two regions. The first paddle 1252 and the second paddle 1254 may be physically separated and insulated from each other.

The power semiconductor die 1210 having a drain electrode formed on one side thereof and a source electrode and a gate electrode formed on the other side thereof may be bonded to the lead frame paddle 1250. The source electrode and gate electrode of the power semiconductor die 1210 may be bonded to the lead frame paddle 1250. The source electrode may be bonded to the first paddle 1252 that is formed in the first region. The gate electrode may be bonded to the second paddle 1254 that is formed in the second region.

The source electrode of the power semiconductor die 1210 may be bonded to the first paddle 1252 through a first bonding member 1282. The gate electrode of the power semiconductor die 1210 may be bonded to the second paddle 1254 through a second bonding member 1284. The first bonding member 1282 and the second bonding member 1284 may be soldering bonding members. The source electrode may be bonded to the first paddle 1252 by soldering, and the gate electrode may be bonded to the second paddle 1254 by soldering.

The area of the power semiconductor die 1210 may be smaller than the area of the lead frame paddle 1250. When viewed from the top, the power semiconductor die 1210 may be disposed inside the lead frame paddle 1250.

The first paddle 1252 that is disposed in the first region of the lead frame paddle 1250 may be extended to form the source lead 1222. The second paddle 1254 that is disposed in the second region of the lead frame paddle 1250 may be extended to form the gate lead 1224. Through such a connection structure, the source electrode may be electrically connected to the source lead 1222 and the gate electrode may be electrically connected to the gate lead 1224 without using a wire.

The drain electrode of the power semiconductor die 1210 may be electrically connected to the drain lead 1226 through the connection member 1290. In this case, the connection member 1290 may be a clip. The clip 1290 may have a wide square form in the drain electrode. Furthermore, through such a wide square form, contact resistance can be reduced, and heat dissipation performance toward the drain electrode can be improved.

One end of the clip 1290 may be bonded to the drain electrode through a third bonding member 1286, and the other end thereof may be bonded to the drain lead 1226 through a fourth bonding member 1288. The third bonding member 1286 and the fourth bonding member 1288 may be soldering bonding members. The clip 1290 may be bonded to the drain electrode and the drain lead 1226 by soldering.

The power semiconductor die 1210 and the clip 1290 may be surrounded by the mold 1270. The mold may be formed of an epoxy molding compound (EMC).

A part of the source lead 1222 and a part of the gate lead 1224 may be included within the mold 1270, and the remaining parts thereof may be exposed to the outside of the mold 1270.

A part that belongs to the drain lead 1226 and to which the clip 1290 is bonded may be included within the mold 1270, and the remaining parts thereof may be exposed to the outside of the mold 1270.

A part of the lead frame paddle 1250 may be exposed to the outside of the mold 1270. Furthermore, the exposed part of the lead frame paddle 1250 may come into contact with a component capable of heat dissipation. For example, the exposed part of the lead frame paddle 1250 may be bonded to a heat sink, and may be exposed to the air.

One surface of the first paddle 1252 that is disposed in the first region of the lead frame paddle 1250 may be exposed to the outside of the mold 1270. Furthermore, the second paddle 1254 that is disposed in the second region of the lead frame paddle 1250 may be disposed within the mold 1270 and insulated from the outside.

As described above, in the second example, heat dissipation performance can be improved because the lead frame paddle 1250 is exposed to the outside of the mold 1270. EMI performance can also be improved because the lead frame paddle 1250 is electrically connected to the source electrode.

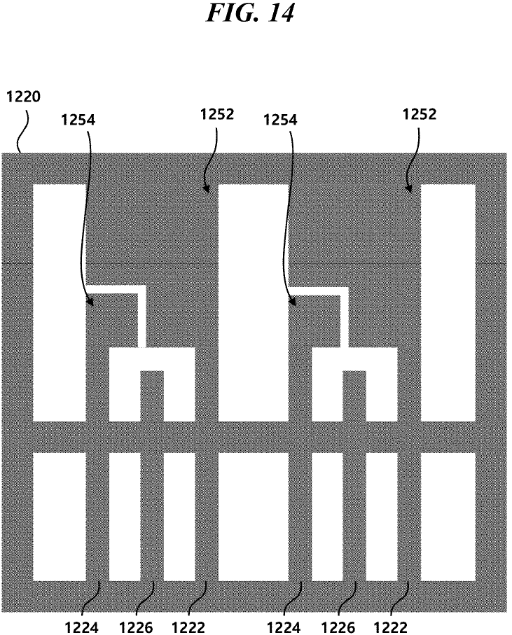

FIGS. 14 to 18 are exemplary diagrams illustrating processes of a method of manufacturing a power semiconductor module according to a second example.

Referring to FIG. 14, in a first process, a lead frame 1220 in which a plurality of lead frame paddles 1252 and 1254, a plurality of source leads 1222, a plurality of gate leads 1224, and a plurality of drain leads 1226 have been formed may be disposed.

The lead frame paddles 1252 and 1254 may be divided into the first paddle 1252 and the second paddle 1254, respectively. Furthermore, in the lead frame 1220, the first paddle 1252 may be connected to the source lead 1222, and the second paddle 1254 may be connected to the gate lead 1224.

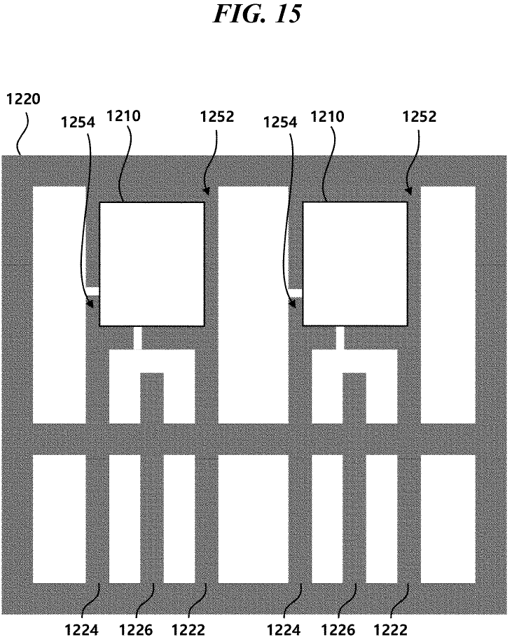

Referring to FIG. 15, in a second process, the power semiconductor die 1210 may be bonded to each of the lead frame paddles 1252 and 1254. A drain electrode may be formed on one side of the power semiconductor die 1210, and a source electrode and a gate electrode may be formed on the other side of the power semiconductor die 1210. The source electrode and the gate electrode may be bonded to the lead frame paddles 1252 and 1254. Specifically, the source electrode may be bonded to the first paddle 1252, and the gate electrode may be bonded to the second paddle 1254.

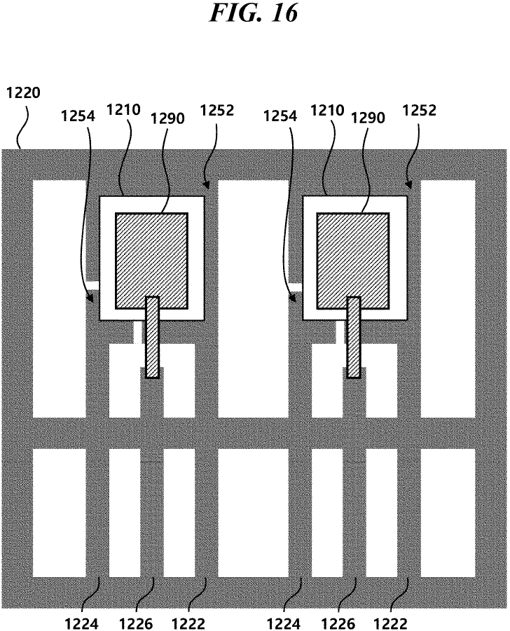

Referring to FIG. 16, in a third process, the drain electrode may be connected to the drain lead 1226 by using the clip 1290.

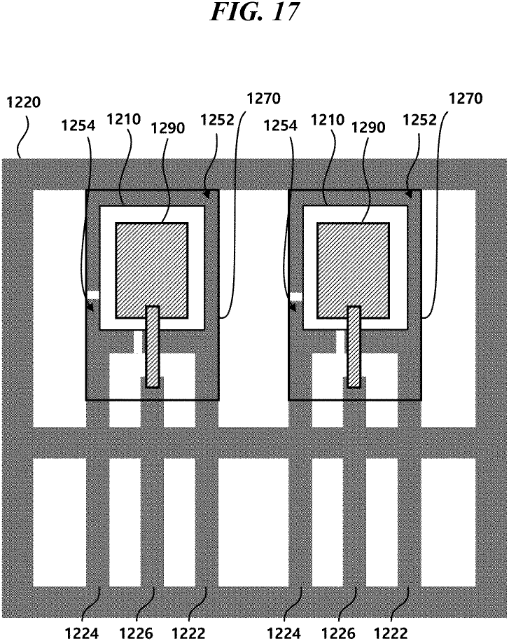

Referring to FIG. 17, in a fourth process, the power semiconductor die 1210 and the clip 1290 may be surrounded by the mold 1270. In this case, the mold 1270 may be formed so that parts of the lead frame paddles 1252 and 1254 are exposed to the outside of the mold 1270.

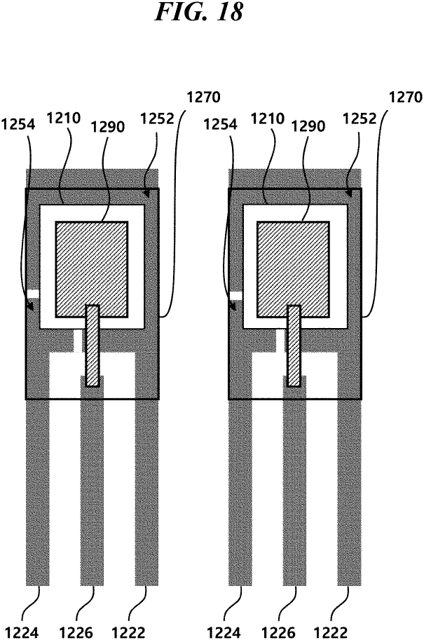

Referring to FIG. 18, in a fifth process, as an unnecessary part is removed from the lead frame, the power semiconductor module can be manufactured.

As described above, according to the present embodiment, heat dissipation performance of the power semiconductor module can be improved. Furthermore, according to the present embodiment, EMI noise in the power semiconductor module can be reduced.

What is claimed is:

1. A power semiconductor module comprising:
a lead frame paddle;
a metal plate, disposed on the lead frame paddle, in a state of being insulated from the lead frame paddle;
a power semiconductor die having a first electrode formed on one side thereof and a second electrode formed on another side thereof, the first electrode being disposed toward the metal plate;
a first lead electrically connected to the first electrode through the metal plate; and
a second lead extended from the lead frame paddle and electrically connected to the second electrode.

2. The power semiconductor module of claim 1, wherein the first electrode is bonded to the metal plate.

3. The power semiconductor module of claim 2, wherein the first lead is electrically connected to the metal plate through a wire.

4. The power semiconductor module of claim 1, wherein:
the power semiconductor die comprises a gate electrode formed on a same side as a side of the second electrode, and
the power semiconductor module further comprises a gate lead electrically connected to the gate electrode through a wire.

5. The power semiconductor module of claim 1, further comprising a mold surrounding the power semiconductor die, wherein a part of the lead frame paddle is exposed to an outside of the mold.

6. The power semiconductor module of claim 5, wherein a part of a surface opposite the one surface of the lead frame paddle is disposed to be thermally in contact with the metal plate in the mold and the remaining part is disposed to be exposed to the outside of the mold.

7. The power semiconductor module of claim 6, wherein an insulating member is disposed between the lead frame paddle and the metal plate.

8. The power semiconductor module of claim 5, wherein the mold is formed of an epoxy molding compound (EMC).

9. A power semiconductor module comprising:
a lead frame paddle;
a power semiconductor die having a first electrode formed on one side thereof and a second electrode formed on another side thereof, the second electrode being bonded to the lead frame paddle;
a first lead electrically connected to the first electrode; and
a second lead extended from the lead frame paddle.

10. The power semiconductor module of claim 9, wherein the first lead is electrically connected to the first electrode through a clip.

11. The power semiconductor module of claim 9, wherein:
the power semiconductor die comprises a gate electrode formed on a same side as a side of the second electrode,
the lead frame paddle is divided into two regions that are electrically insulated, and
the second electrode is bonded to a first region of the lead frame paddle and the gate electrode is bonded to a second region of the lead frame paddle.

12. The power semiconductor module of claim 11, further comprising a gate lead extended from the second region of the lead frame paddle.

13. The power semiconductor module of claim 11, further comprising a mold surrounding the power semiconductor die, wherein one surface of the first region of the lead frame paddle is exposed to an outside of the mold.

14. The power semiconductor module of claim 13, wherein the second region of the lead frame paddle is disposed within the mold.

15. A method of manufacturing a power semiconductor module, comprising:
disposing a lead frame comprising a lead frame paddle, a first lead, a second lead, and a gate lead, wherein the second lead is connected to the lead frame paddle;
bonding, to the lead frame paddle, a second electrode of the power semiconductor die having a first electrode formed on one side thereof and the second electrode formed on another side thereof;
electrically connecting the first lead and the first electrode; and
forming a mold to surround the power semiconductor die.

16. The method of claim 15, wherein, in forming the mold, the mold is formed such that a part of the lead frame paddle is exposed to the outside of the mold.

17. The method of claim 15, wherein:
the lead frame paddle is divided into two regions that are electrically insulated, and
in bonding the second electrode to the lead frame paddle, the second electrode is bonded to a first region of the lead frame paddle and a gate electrode of the power semiconductor die is bonded to a second region of the lead frame paddle.
